(19) United States
(12) Patent Application Publication
(10) Pub. No.: US 2018/0306861 A1
(43) Pub. Date: Oct. 25, 2018

(54) MICROPROCESSOR INTERFACES

(71) Applicant: Nordic Semiconductor ASA, Trondheim (NO)

(72) Inventor: Joar Olai Rusten, Trondheim (NO)

(73) Assignee: Nordic Semiconductor ASA, Trondheim (NO)

(21) Appl. No.: 15/771,339

(22) PCT Filed: Oct. 25, 2016
(86) PCT No.: PCT/GB2016/053321

§ 371 Date: Apr. 27, 2018

(30) Foreign Application Priority Data
Oct. 29, 2015 (GB) 1519120.8

(51) Int. Cl. G01R 31/317; G01R 31/28; G01R 31/3177

(52) U.S. Cl. CPC G01R 31/31705; G01R 31/2851; G01R 31/31721; G01R 31/31719; G01R 31/3177

(57) ABSTRACT

An integrated circuit device comprises: a first power domain (100) including a processor (2) and non-volatile memory (10) connected to the processor; and a second power domain (200) including an access port (12) connected to the non-volatile memory. The access port is further connected to an electrical interface (4) suitable for connection to a debugger.

This invention relates to physical interfaces to integrated circuit microprocessor devices, particularly to interfaces that might be used by a product designer incorporating the device into a larger product.

Modern electronic devices, particular system-on-chip (SoC) devices, are often equipped with a number of ports, which may be connected to a physical pin on the device such that the device may interact with peripheral devices. When designing a system that utilises such a device, the designer will usually configure the numerous ports for various functions as desired. For example, some of the ports may be used for data input, data output, connection to an antenna etc. The designer will also usually need to carry out debugging (i.e. identifying and removing errors) at various stages during the design process.

In order to carry out debugging, the designer might access the device using an access port. This access port allows the designer to interface with the device following an error becoming apparent, analyse the situation to identify the cause of the error and then perform some corrective action (such as resetting the device, clearing registers etc.) in order to rectify the error and continue the design process.

However, an issue can arise wherein the error may cause the whole device to be “locked up” or “bricked”, preventing the designer from doing anything to correct the error. A particularly illustrative example would be that the designer inadvertently shorts an external reset pin to ground, which will cause the entire device to be stuck in a reset loop. Since the whole device is constantly being reset, the designer cannot do anything meaningful via the access port. Such a situation may not be easily apparent from inspection of the external circuit to which the device is connected.

Another example of such an issue is the device being stuck in a persistent sleep mode from which it cannot be woken e.g. the device being given a command to enter sleep mode within a set of device start-up instructions

When viewed from a first aspect, the present invention provides an integrated circuit device comprising:
a first power domain including a processor and non-volatile memory connected to the processor; and
a second power domain including an access port connected to the non-volatile memory, the access port being further connected to an electrical interface suitable for connection to a debugger.

It will be appreciated that by arranging the device such that the access port is in a separate power domain to the rest of the device, it can be always accessible. In a situation such as that outlined above wherein a reset pin has been shorted to ground, only the first power domain will be stuck in the reset loop while the second, independent power domain is still fully functional. As the access port has a direct connection to the non-volatile memory, it can be used to bring the device out of the reset loop without having to access the processor. This can, for example, be achieved by: disabling the soft reset functionality of the device such that only the debugger can issue soft reset commands via the access port, thus bringing the first power domain out of the reset loop or sleep state; clearing the non-volatile memory to erase the instructions that caused the reset loop or sleep state; and subsequently resetting the device.

There are a number of electrical interfaces suitable for connection to debuggers that are known in the art per se. In some embodiments, the electrical interface comprises a Serial Wire Debug (SWD) interface connected to the access port via a Serial Wire Debug Port (SW-DP). In other embodiments the electrical interface comprises a Joint Test Action Group (JTAG) interface connected to the access port via a Joint Test Action Group Debug Port (JTAG-DP). The SWD and JTAG interfaces are commonly used by debuggers. Advantageously, the device of the present invention is configured to cater to both standards and thus in some embodiments, the electrical interface comprises a hybrid Serial Wire and Joint Test Action Group Debug Port (SWJ-DP).

Conventionally, in order to carry out the debugging process and recover the device, the designer will often wish to remove the problematic firmware, which usually involves instructing the processor to carry out an erase function to clear the content of the non-volatile memory. In some embodiments, the access port is arranged to erase the non-volatile memory. This advantageously allows the designer to erase the content of the non-volatile memory while completely bypassing the processor.

Devices to which the principles of this invention particularly apply are commonly sold on to customers who will integrate the device into a larger system and will often program the device with proprietary firmware. The firmware is usually sensitive and belongs to the customer, who would not want end users to be readily able to obtain the firmware, in machine code or source code form. In some embodiments, the device comprises a protection module arranged to prevent data being read from the non-volatile memory via the access port. This protection module may have a flag which, once set, prevents data being read from the access port. In order to disable the protection, any such end user would have to clear the protection flag, which wipes the non-volatile memory, thereby avoiding access to the confidential contents thereof.

There are a number of conditions that might cause an electronic device to reset. For example, a device is “hard reset” when it is power cycled (i.e. powered off and on again), or when an external reset command is given that causes the device to perform a “soft reset”. In some embodiments, the second power domain is arranged such that it is only reset when the device is switched from being powered off to being powered on. This means that soft resets of the device only reset the first power domain, leaving the second power domain in which the access port resides unaffected by the reset command.

While the access port could have direct access to the non-volatile memory, in some embodiments the access port is connected to the non-volatile memory via a non-volatile memory control (NVMC) unit. This NVMC unit can manage the non-volatile memory and while it is typically arranged within the first power domain, it is also possible to arrange it within the second power domain.

The Applicant has appreciated that the present invention also allows for the debugger to query the device, regardless of the operating condition of said device. In some embodiments, the device is arranged to provide performance information to the debugger. In some further embodiments, the performance information comprises a current operation mode. Additionally or alternatively, the performance information may comprise a current error level.

It will be appreciated by those skilled in the art that there are a number of non-volatile memory technologies to which the principles of this invention could be readily applied. However in some embodiments, the non-volatile memory comprises flash memory. The ability to erase and re-write the non-volatile memory is particularly advantageous and for that reason the use of flash memory is advantageous.

Certain embodiments of the invention will now be described, by way of example only, with reference to the accompanying drawings in which:

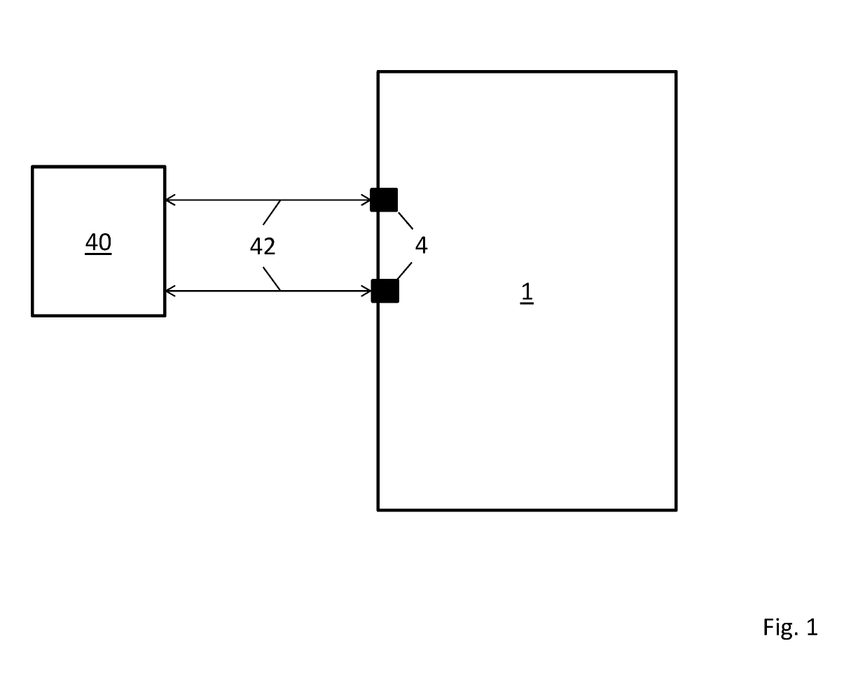

FIG. 1 shows a device in accordance with an embodiment of the present invention connected to an external debugger;

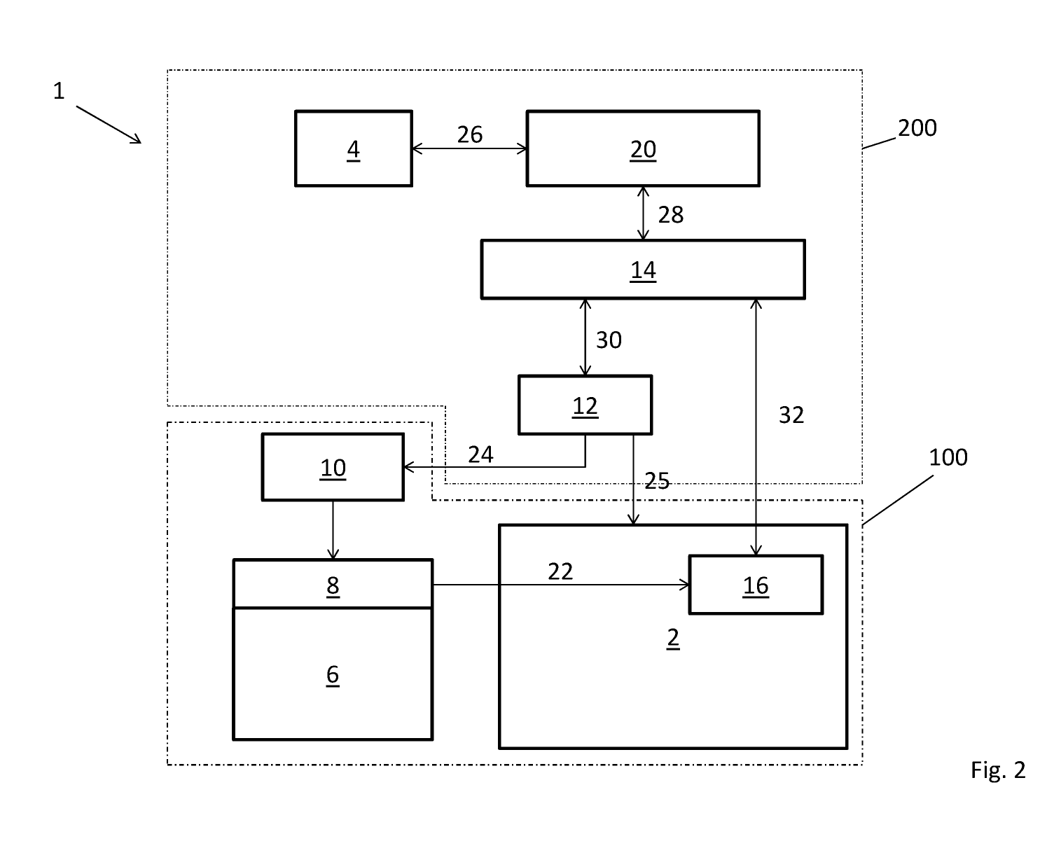

FIG. 2 shows an overview of the device of FIG. 1;

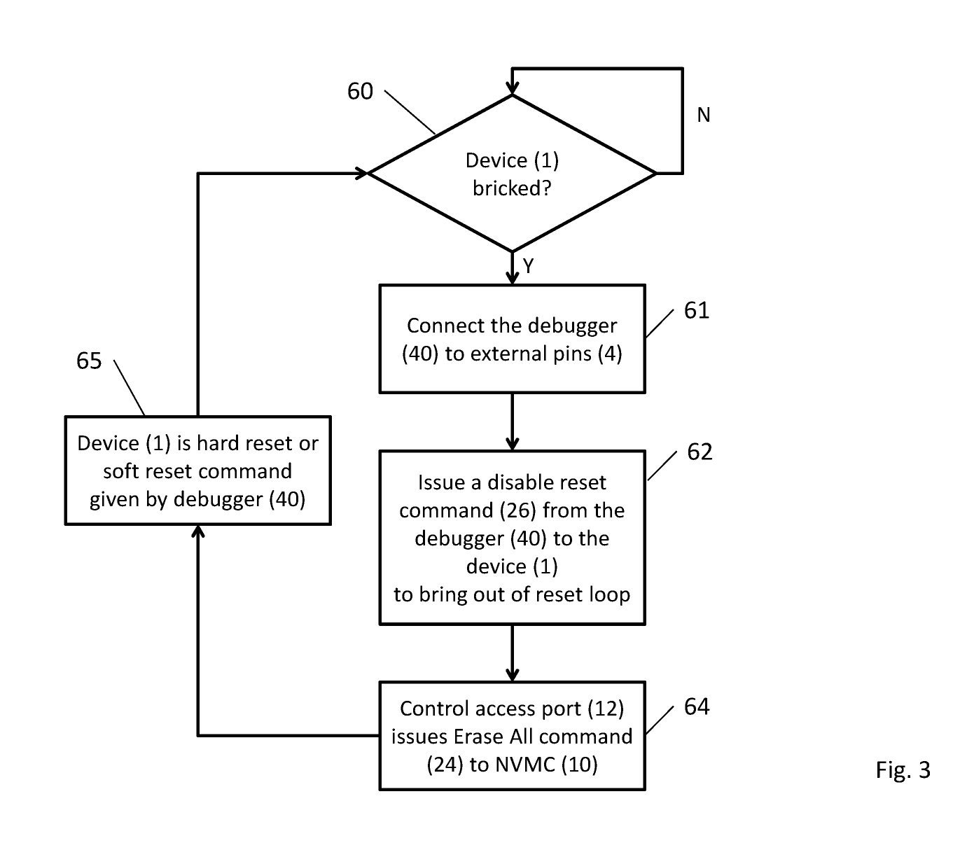

FIG. 3 shows a flowchart illustrating a mode of recovering the device of FIG. 1 from a bricked state; and

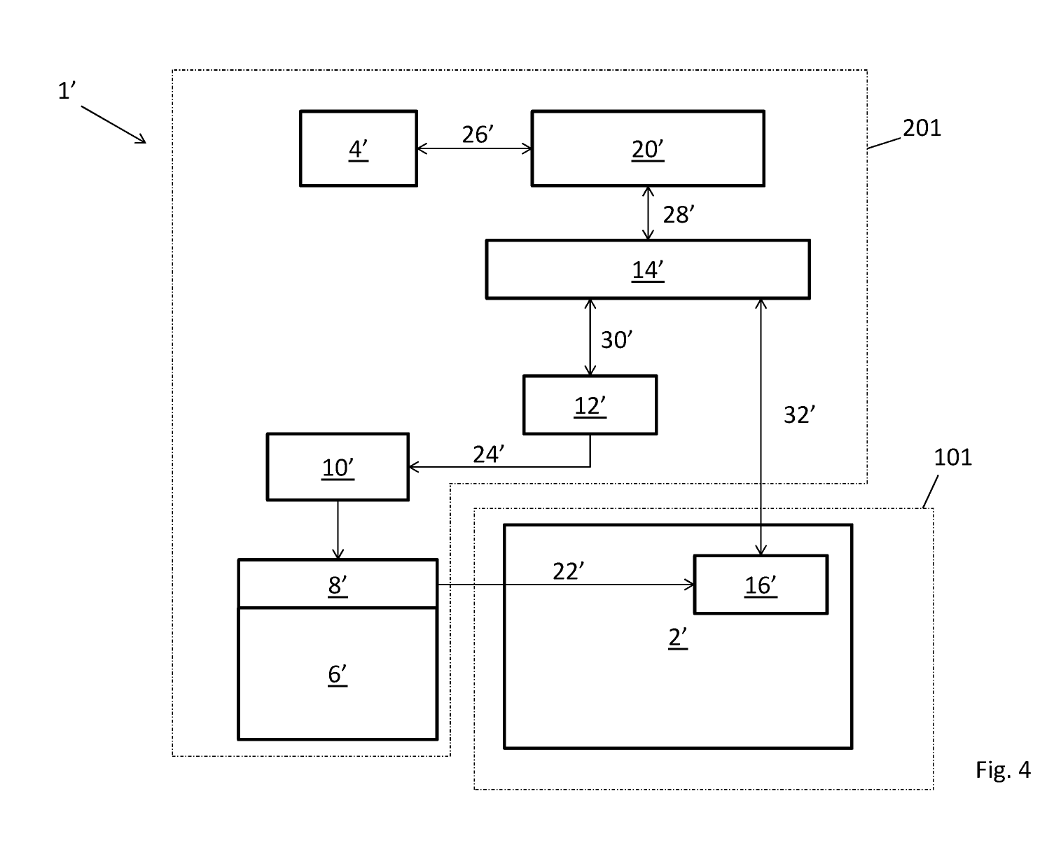

FIG. 4 shows an overview of the device in accordance with another embodiment of the present invention.

FIG. 1 shows a system-on-chip (SoC) integrated circuit device 1 in accordance with an embodiment of the present invention connected to an external debugger 40. The device 1 includes a number of external pins 4 to which an external debugger 40 is connected.

In this particular embodiment, the debugger 40 utilises the Serial Wire Debug (SWD) interface, an ARM® standard protocol that utilises two bi-directional wires 42. The protocol itself is defined in the ARM® Debug Interface v5 and ARM® Debug Interface v5.1, both of which are incorporated herein by reference. However, this particular embodiment is not limiting, and the principles of this invention can be readily applied to other interfaces such as the Joint Action Test Group (JTAG) interface, as well as other standard and proprietary debugging interfaces.

The ARM® Debug Interface (ADI) includes: Debug Ports (DPs), which are used to access the DAP from an external debugger such as the debugger 40; and Access Ports (APs), to access on-chip system resources within the integrated circuit device 1.

FIG. 2 shows an overview of the device 1 shown described above with reference to FIG. 1. The device 1 includes a processor 2 e.g. an ARM® Cortex®-M4, and also shown are the set of pins 4 to which the external debugger 40 can be connected as shown in FIG. 1 above. The device 1 also includes flash memory (i.e. non-volatile memory) 6, which is used to store firmware uploaded to the device 1 by the designer, as well as for use by the firmware itself. The flash memory 6 is arranged to be accessed using a memory access port 16 within the processor 2.

The set of external pins 4 in this particular embodiment are suitable for connection to either a Serial-Wire-Debug (SWD) debugger, or a Joint Action Test Group (JTAG) debugger in accordance with the IEEE-1149.1 standard, as the device 1 is provided with a hybrid Serial Wire and Joint Test Action Group Debug Port (SWJ-DP) 20.

Within the device 1 is a control access port 12 which is connected to the SWJ-DP 20 via a Debug Access Port (DAP) Bus Interface 14, as defined within the ADI. The DAP Bus Interconnect 14 acts as an intermediate layer between debug ports (i.e. the SWJ-DP 20) and the control access port 12 and allows the debugger 40 to access the processor 2 in real-time without interrupts. The DAP Bus Interconnect 14 is implemented as a multiplexer (mux) which allows the SWJ-DP 20 to access both the memory access port 16 within the processor 2 and the control access port 12.

The control access port 12 is then connected to a non-volatile memory control (NVMC) unit 10, which has direct control over the flash memory 6. The flash memory 6 contains a number of user information configuration registers (UICR) 8. These registers 8 can be used to store user specific settings, and in this case are used to store a protection flag. The firmware uploaded to the flash memory 6 by the designer is usually sensitive. The setting of the protection flag prevents data being read from the flash memory 6 via the control access port 12. This protection module has a flag which, once set, prevents data being read from the control access port 12. In order to disable the protection, the end user would need to clear the protection flag, which requires erasing all of the flash memory 6 including anything else that may be stored in it.

The device 1 is divided into two power domains 100, 200. The first power domain 100 includes the processor 2, associated memory access port 16, NVMC 10, and flash memory 6, while the second power domain 200 includes the external pins 4, SWJ-DP 20, DAP Bus Interconnect 14 and control access port 12.

If the device 1 is “hard reset”, i.e. the device 1 is powered off and subsequently powered on again, both power domains 100, 200 will be reset. However, in the case of a “soft reset” wherein an external reset command is given to the device 1, this will only cause the reset of the first power domain 100, thus resetting the processor 2, leaving the second power domain 200 unaffected.

If, for example, the processor 2 is reset when a logic “0” signal e.g. ground is applied to a reset pin located somewhere on the device 1, it is possible that a designer wishing to utilise the device 1 in a system might inadvertently ground the pin, causing the device 1 to constantly reset, preventing it from starting up correctly. Conventionally, this renders a device virtually unusable, often referred to as the device being “bricked”. The device 1 embodying the present invention however can be recovered from this state, as will be described below with reference to FIG. 3.

FIG. 3 shows a flowchart illustrating a mode of recovering the device 1 of FIG. 1 from a bricked state. With the device 1 embodying the present invention, the reset loop does not affect the second power domain 200, and only the components within the first power domain 100 are unusable. A designer who determines that the device 1 is bricked (step 60) can connect the debugger 40 to the external pins 4 (step 61), and issue a disable reset command 26 to the device 1 via the SWJ-DP 20 in order to bring the device 1 out of the reset loop (step 62). This disable reset command 26 is then relayed via the connection 28 from the SWJ-DP 20 to the DAP Bus Interconnect 14, and subsequently via the connection 30 to the control access port 12. The disable reset command 26 disables the soft reset functionality of the device 1, bringing the first power domain 100 out of the reset loop. The control access port 12 then issues an Erase All command 24 to the NVMC unit 10 (step 64), which in turn completely erases the content of the flash memory 6. The device can then be reset (step 65), either via a hard reset or via a command given by the control access port 12, after which time the device 1 will no longer be bricked.

It is worth noting that while NVMC unit 10 may in general be able to write to memory, erase a page from memory, erase the entire memory etc., the control access port 12 is only able to issue Erase All commands to the NVMC 10. This further enhances the security of the device as it prevents an end-user being able to erase only the protection flag in the UICR 8 without erasing the rest of the flash memory 6.

The independent second power domain 200 also permits information relating to the operation of the device 1 to be read by the debugger 40 via the external pins 4, regardless of whether the device 1 is stuck in a reset loop, a persistent sleep mode, etc.

FIG. 4 shows an overview of a device in accordance with another embodiment of the present invention. Prime reference numerals indicate like components to those described hereinabove.

The device 1′ is divided into two power domains 101, 201. In this embodiment, the first power domain 101 includes only the processor 2′ and associated memory access port 16′, while the second power domain 201 includes the external pins 4′, SWJ-DP 20′, DAP Bus Interconnect 14′, control access port 12′, NVMC 10′, and flash memory 6′.

If the device 1′ becomes stuck in a reset loop, the designer can connect the debugger 40′ to the external pins 4′, and issue a disable reset command 26′ to bring the device 1′ out of the reset loop. This disable reset command 26′ is then relayed via the connection 28′ from the SWJ-DP 20′ to the DAP Bus Interconnect 14′, and subsequently via the connection 30′ to the control access port 12′. The control access port 12′ then issues an Erase All command 24′ to the NVMC unit 10′, which in turn completely erases the content of the flash memory 6′.

Thus it will be seen that a device has been described in which an independent power domain provides an independent, always available mechanism for restoring said device from an unusable state. Although particular embodiments have been described in detail, it will be appreciated by those skilled in the art that many variations and modifications are possible using the principles of the invention set out herein.

1. An integrated circuit device comprising:
a first power domain including a processor and non-volatile memory connected to the processor; and
a second power domain including an access port connected to the non-volatile memory, the access port being further connected to an electrical interface suitable for connection to a debugger.

2. The device as claimed in claim 1, wherein the electrical interface comprises a Serial Wire Debug (SWD) interface connected to the access port via a Serial Wire Debug Port (SW-DP).

3. The device as claimed in claim 1, wherein the electrical interface comprises a Joint Test Action Group (JTAG) interface connected to the access port via a Joint Test Action Group Debug Port (JTAG-DP).

4. The device as claimed in claim 1, wherein the electrical interface comprises a hybrid Serial Wire and Joint Test Action Group Debug Port (SWJ-DP).

5. The device as claimed in claim 1, wherein the access port is arranged to erase the non-volatile memory.

6. The device as claimed in claim 1, wherein the device comprises a protection module arranged to prevent data being read from the non-volatile memory via the access port.

7. The device as claimed in claim 1, wherein the second power domain is arranged such that it is only reset when the device is switched from being powered off to being powered on.

8. The device as claimed in claim 1, wherein the access port is connected to the non-volatile memory via a non-volatile memory control (NVMC) unit.

9. The device as claimed in claim 1, wherein the device is arranged to provide performance information to the debugger.

10. The device as claimed in claim 9, wherein the performance information comprises a current operation mode.

11. The device as claimed in claim 9, wherein the performance information comprises a current error level.

12. The device as claimed in claim 1, wherein the non-volatile memory comprises flash memory.
